(19) United States
(12) Patent Application Publication
(10) Pub. No.: US 2009/0039910 A1
(43) Pub. Date: Feb. 12, 2009

(54) TEST APPARATUS FOR SEMICONDUCTOR MODULES

(75) Inventors: Gerd Frankowsky, Hoehenkirchen-Siegertsbrunn (DE); Roman Mayr, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/174,302

(22) Filed: Jul. 16, 2008

(30) Foreign Application Priority Data
Jul. 16, 2007 (DE) 10 2007 033 127.6

(51) Int. Cl. G01R 1/073

(52) U.S. Cl. 324/761

(57) ABSTRACT

A test apparatus for semiconductor modules. One embodiment provides a test system. The test system includes a handler configured to receive at least one semiconductor module. The test system is equipped with a plurality of different pin cards. The handler has at least two independent groups of test receptacles.

### CROSS-REFERENCE TO RELATED APPLICATIONS

This Utility Patent Application claims priority to German Patent Application No. DE 10 2007 033 127.6 filed on Jul. 16, 2007, which is incorporated herein by reference.

### BACKGROUND

Backend (BE) testing of a semiconductor module, that is to say the final testing before it is delivered to customers, generally includes a plurality of individual test processes, insertions, that is to say the practice of respectively supplying the semiconductor module to different test cells. The subdivision of the test contents, for example temperature and/or frequency, to which the semiconductor module is exposed, among the individual test processes is essentially determined by the test costs in addition to technical reasons (the semiconductor module must be exposed to a temperature of 80° C., for example).

A test cell is formed by a test system and a handler having a plurality of test receptacles (also called sockets). The test system is also referred to as an ATE unit (ATE=Automatic Test Equipment). The semiconductor modules to be tested are delivered to the input of the test cell in trays. In a first step, the handler then removes a number of modules from the tray and inserts them into respective test receptacles of a load board. The test system then tests the function of these semiconductor modules which have been inserted into the test receptacles. After the test has been concluded, the handler removes the semiconductor modules from the test receptacles and, depending on the test result, deposits them in different trays at the output of the test cell.

Tests in further test cells then follow. For example, a test in a handler is carried out in a first test cell having a test system which has been set to 100 MHz, a temperature of −20° C. prevailing in a chamber surrounding the test receptacles. Those semiconductor modules which pass this test and are not singled out as being defective (fail) are then supplied to a second test cell in order to be subjected to a test at 100 MHz again but at a higher temperature of 80° C. This may also be then followed by a test in a third test cell in which the test system carries out a test at 500 MHz, the temperature in the chamber surrounding the test receptacles being 80° C. in this case. Further tests in additional test cells are possible.

It is thus customary to subdivide the tests among different test cells having different test systems and different chamber temperatures, for example. This presupposes transportation of the semiconductor modules between the test cells, which inevitably results in losses caused by the transportation and also signifies an increased space requirement for the individual test cells. Test data must also be forwarded from preceding test cells for final sorting-out according to power classes of the semiconductor components and must be chosen in a time-consuming manner.

The test apparatus used here uses pin cards of different frequencies, namely, for example, low-speed pin cards and high-speed pin cards for tests having signals at 100 MHz (low-speed pin cards) and 500 MHz (high-speed pin cards), for example. Instead of different frequencies, different amplitudes of currents and voltages may also be used if appropriate.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a diagrammatic illustration of one embodiment of a test system having low-speed pin cards and high-speed pin cards, with a load board.

FIG. 2 illustrates one embodiment of a test cell having the test system of FIG. 1 and with additional details of an actual test sequence.

FIG. 3 illustrates details of the test cell of FIG. 2.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

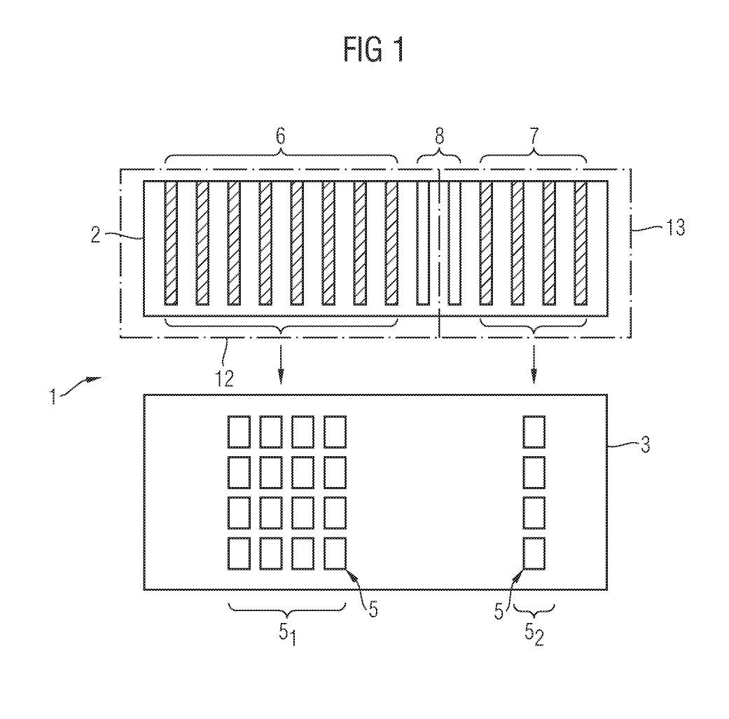

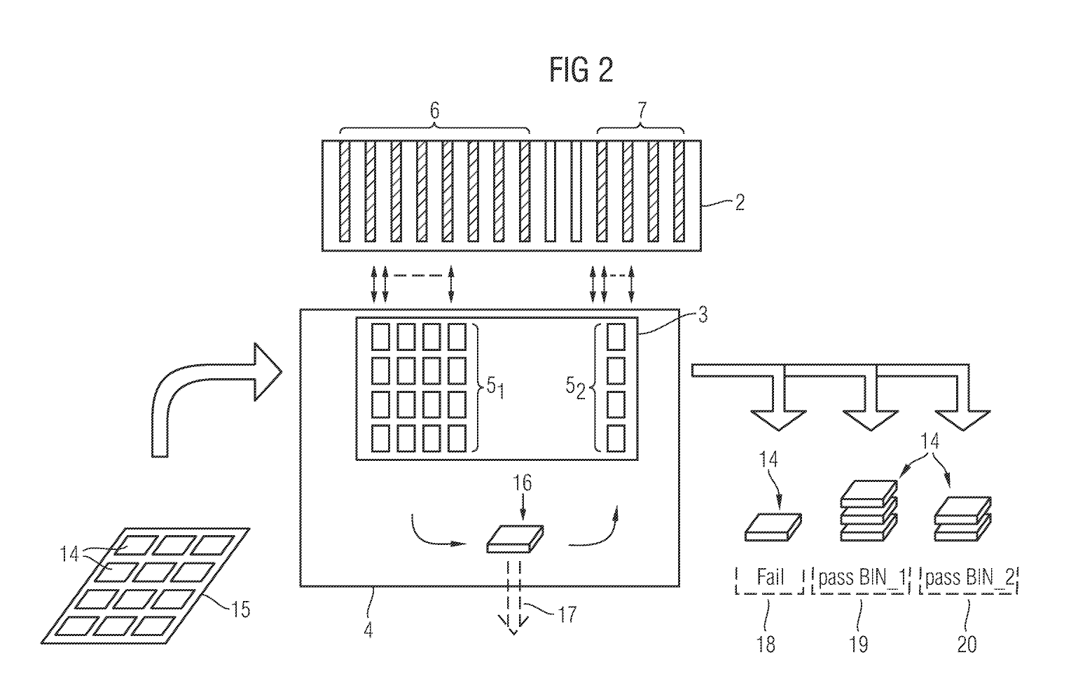

FIG. 1 illustrates a test cell 1 having a test system 2 and a load board 3 which has test receptacles 5 and is also referred to as a PCB (Printed Circuit Board). The assignment of the load board 3 having the test receptacles 5 to a handler 4 can be seen diagrammatically in FIG. 2.

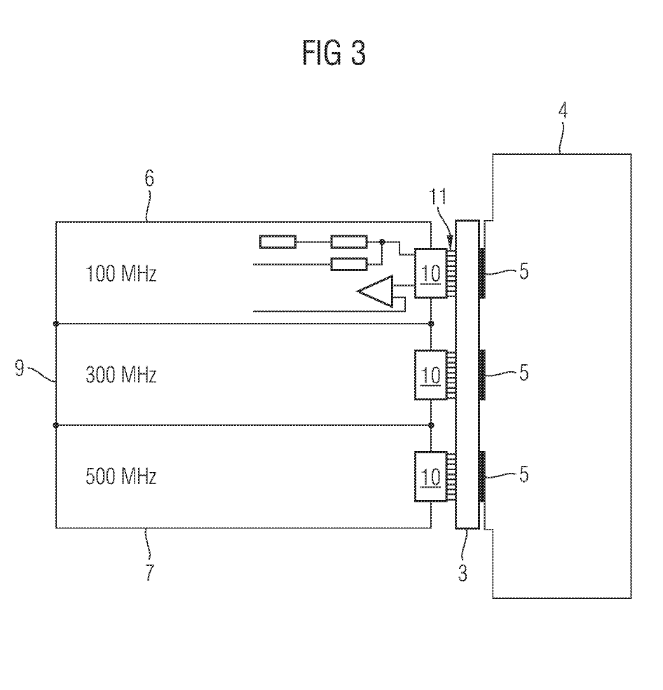

The test system 2 has low-speed pin cards 6 for a test at 100 MHz, for example, and high-speed pin cards 7 for a test at 500 MHz, for example. FIG. 3 illustrates a diagrammatic plan view of a respective pin card 6 or 7 of this type. Pin cards 9 for a test at a medium speed, that is to say 300 MHz, can be inserted, for example, if required into free spaces 8 for additional pin cards. However, the exemplary embodiment of FIG. 1 uses only the low-speed pin cards 6 and the high-speed pin cards 7. The test system 2 can form a single test head, with the result that both the low-speed pin cards 6 and the high-speed pin cards 7 are accommodated in this test head. However, it is likewise also possible to provide a respective separate test head 12 and 13 for the low-speed pin cards 6 and for the high-speed pin cards 7 for the test system 2.

As can be seen in FIG. 3, the pin cards 6, 7, 9 have respective interfaces 10 having needles 1 or pins or other means which can be used to contact-connect contacts on the load board 3 which forwards the test signals to semiconductor modules placed in the test receptacles 5, that is to say the pins thereof. In this case, defined temperatures of, for example, −20° C. or +80° C. prevail in chambers surrounding the individual test receptacles 5.

The pin cards 6, 7 and 9 feed defined test signals, via the load board 3, into the semiconductor modules, which have been inserted into the test receptacles 5, and may also receive signals emitted by the semiconductor modules if appropriate in order to evaluate the signals, as is diagrammatically indicated by a few circuit elements for the test system 6 in FIG. 3.

If the test system 2 has two separate test heads, that is to say the first test head 12 for the low-speed pin cards 6 and the second test head 13 for the high-speed pin cards 7, these test heads 12, 13 of the test system 2 may be assigned separately to the load board 3, as is illustrated by two arrows in FIG. 1. If, in contrast, there is only a single test head for the low-speed pin cards 6 and the high-speed pin cards 7, this test head is assigned as a whole to the load board 3 by the handler 4.

As can also be seen from FIG. 1, the pin cards 6 and 7 may be assigned to respective separate groups 5₁ and 5₂ of test receptacles 5 in the handler 4. In this case, the handler 4 thus has two independent groups of test receptacles. Yet further groups of test receptacles, for instance a group for the pin cards 9 of medium speed, may also be provided if necessary. The number n of test receptacles in the individual groups 5₁ and 5₂ should be selected in such a manner that they can be combined in the ratio of the test times T₁ in the receptacles in the group 5₁ to the test times T₂ in the receptacles in the group 5₂. For example, the first group 5₁ may have sixteen receptacles and the second group 5₂ may have four test receptacles (n₂). The following applies: T₁/T₂=n₁/n₂. This is advantageous for optimum use of the test apparatus, as will also be explained below.

FIG. 2 illustrates the method for the manner in which individual semiconductor modules 14 on a tray 15 are removed by the handler 4 and are supplied to the load board 3 in order to be exposed first to a low-speed test using the low-speed pin cards 6 in the board's test receptacles in the group 5₁ and then, after passing through an intermediate store 16, to a high-speed test using the high-speed pin cards 7 in the test receptacles in the group 5₂ using only this one load board 3. In this case, the handler 4 removes the semiconductor modules 14 from the tray 15 and first of all inserts them into the first group 5₁ of test receptacles 5 of the load board 3. The first test, that is to say the low-speed test in the present example, is then started at a particular first temperature of, for example, −20° C. using the low-speed pin cards 6 in the test system 2. At the end of the test, the test data which are needed to assess the semiconductor module are buffered in the test system 2. The semiconductor modules in the test receptacles 5 in the first group 5₁ are removed from the receptacles by the handler 4 and are supplied to the intermediate store 16. Semiconductor modules which have not passed the first test, that is to say have been rated as “fail”, may already be singled out here if required, as is indicated by an arrow 17. The handler 4 is thus used to respectively remove and move the semiconductor modules and, in one embodiment, also to supply the load board 3 which has been fitted with the semiconductor modules 14 to the test system 2. In this respect, the load board 3 can be considered to be part of the handler 4.

The semiconductor modules are then supplied from the intermediate store 16 to the second group 5₂ of test receptacles 5 of the handler 4 and are subjected to a second test, a high-speed test in the present example, at a frequency of 500 MHz, for example, and a temperature of 80° C. using the pin cards 7. In this case too, the test results for the individual semiconductor modules are stored in the test system 2. Yet further tests may then follow if required.

After the last test has been concluded, the semiconductor modules are finally deposited in different trays 18, 19, 20, namely the tray 18 for semiconductor modules which have been rated as “fail”, the tray 19 for semiconductor modules which have been rated as “average” (Pass BIN-1) and the tray 20 for semiconductor modules which have been rated as “good” (Pass BIN-2).

In order to be able to make optimum use of the test apparatus as a whole, the quotient of test time, that is to say the time for which the semiconductor modules remain, for example, in the group 5₁ of test receptacles 5, and “parallelism”, that is to say the number of semiconductor modules which are simultaneously tested in a group, should be as constant as possible.

The test apparatus readily makes it possible to assess semiconductor modules with and without DfT features (DfT=Design for Test) and allows optimization of the functionality of a DRAM, for example, as regards the core (memory array) and speed (interface) test. An ALPG (Algorithmic Pattern Generator) is thus required, for example, for a core test, which can be readily achieved by using appropriate selection of the pin cards. A speed test supports a limited complete functional test as well as BERT functions (BERT=Bit Error Rate Test), in one embodiment in the case of a DRAM. The test apparatus may have a modular structure, the individual test systems then being equipped with pin cards of different power. For example, a test system may also be assigned to two handlers, with the result that the groups 5₁ and 5₂ in FIG. 1 each belong to a separate handler. In one embodiment, as already mentioned, separate test heads 12, 13 may also be allocated to only one handler.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A test apparatus for semiconductor modules, comprising:
a test system having pin cards; and
a handler configured to receive at least one semiconductor module,
wherein the test system is equipped with a plurality of different pin cards, and
wherein the handler has at least two independent groups of test receptacles.

2. The test apparatus of claim 1, wherein the test system comprises at least two independent test heads.

3. The test apparatus of claim 1, comprising wherein the test system has only one test head.

4. The test apparatus of claim 1, comprising wherein an intermediate store is provided between groups of test receptacles of the handler.

5. The test apparatus of claim 4, comprising wherein the intermediate store is connected to a tray for defective semiconductor modules.

6. The test apparatus of claim 1, comprising wherein the test system has pin cards for a low-speed test and pin cards for a high-speed test.

7. The test apparatus of claim 6, comprising wherein further pin cards can be inserted into free spaces of the test system for a further test.

8. The test apparatus of claim 1, comprising wherein the number of test receptacles in the individual groups of test receptacles is selected in such a manner that its quotient corresponds to the quotient of the test times in the respective groups of test receptacles.

9. The test apparatus of claim 1, comprising wherein the quotient of test time in a group of test receptacles and parallelism is constant.

10. The test apparatus of claim 1, comprising wherein the tested semiconductor modules can be deposited in different trays.

11. The test apparatus of claim 1, comprising wherein a load board is provided between the test system and the handler.

12. A method for testing semiconductor modules, comprising:
passing the semiconductor modules through a handler; and
testing using a test system having different pin cards.

13. A test apparatus for semiconductor modules, comprising:
a test system having pin cards for a low-speed test and pin cards for a high-speed test; and
a handler which receives at least one semiconductor module,
wherein the test system is equipped with a plurality of different pin cards,
wherein the handler has at least two independent groups of test receptacles, and
wherein the number of test receptacles in the individual groups of test receptacles is selected in such a manner that its quotient corresponds to the quotient of the test times in the respective groups of test receptacles.

14. A test apparatus for semiconductor modules, comprising:
a test system having pin cards; and
a handler configured to receive at least one semiconductor module,
wherein the test system is equipped with a plurality of different pin cards

15. The test apparatus of claim 14, wherein the test system comprises at least two independent test heads.

16. The test apparatus of claim 14, comprising wherein the test system has only one test head.

17. The test apparatus of claim 14, comprising wherein the test system has pin cards for a low-speed test and pin cards for a high-speed test.

18. The test apparatus of claim 17, comprising wherein further pin cards can be inserted into free spaces of the test system for a further test.

19. The test apparatus of claim 14, comprising wherein the number of test receptacles in the individual groups of test receptacles is selected in such a manner that its quotient corresponds to the quotient of the test times in the respective groups of test receptacles.

20. A test apparatus for semiconductor modules, comprising:
a test system having pin cards; and
a handler which receives at least one semiconductor module,
wherein the handler has at least two independent groups of test receptacles.

21. The test apparatus of claim 20, comprising wherein an intermediate store is provided between groups of test receptacles of the handler.

22. The test apparatus of claim 21, comprising wherein the intermediate store is connected to a tray for defective semiconductor modules.

23. The test apparatus of claim 20, comprising wherein the test system has pin cards for a low-speed test and pin cards for a high-speed test.

24. The test apparatus of claim 23, comprising wherein further pin cards can be inserted into free spaces of the test system for a further test.

25. The test apparatus of claim 20, comprising wherein the number of test receptacles in the individual groups of test receptacles is selected in such a manner that its quotient corresponds to the quotient of the test times in the respective groups of test receptacles.
